(19) United States
(12) Patent Application Publication
(10) Pub. No.: US 2006/0284227 A1
(43) Pub. Date: Dec. 21, 2006

(54) Capacitor device having low dependency of capacitance value change upon voltage

(75) Inventor: Takayuki Kamiya, Iwata-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION

(21) Appl. No.: 11/453,886

(22) Filed: Jun. 16, 2006

(30) Foreign Application Priority Data
Jun. 17, 2005 (JP) 2005-177237

(51) Int. Cl. H01L 29/94

(52) U.S. Cl. 257/296

(57) ABSTRACT

Capacitors are formed on an insulating film covering the surface of a semiconductor substrate. Each capacitor is constituted of a lower electrode layer of doped silicon, a dielectric film of silicon oxide formed on the lower electrode and an upper electrode layer of polycide formed on the dielectric film. Capacitors are divided into first and second groups. In the first group, the lower electrode layers are interconnected to form a first terminal and the upper electrode layers are interconnected to form a second terminal. In the second group, the upper electrodes are all connected to the first terminal and the lower electrodes are all connected to the second terminal. A capacitor device is provided which mitigates a capacitance value change dependency upon an applied voltage and is easy to be manufactured.

### CROSS REFERENCE TO RELATED APPLICATION

This application is based on and claims priority of Japanese Patent Application No. 2005-177237 filed on Jun. 17, 2005, the entire contents of which are incorporated herein by reference.

### BACKGROUND OF THE INVENTION

A) Field of the Invention

The present invention relates to a capacitor device suitable for use in an integrated circuit or the like, and more particularly to a capacitor device having a plurality of capacitors whose upper and lower electrode layers sandwiching a dielectric film are made of a semiconductor layer of polysilicon or the like.

B) Description of the Related Art

A capacitor device for an integrated circuit is known which has a plurality of metal oxide semiconductor (MOS) type capacitors having as its first terminal the source and drain electrodes of a MOS type field effect transistor (FET) and a substrate electrode interconnected together, and as its second terminal the gate electrode (e.g., refer to JP-A-HEI-7-221599 and JP-A-2002-217304).

Although a MOS type capacitor has an advantage that it can be formed easily by using the processes of forming a MOS type transistor, it has a disadvantage that a degree of a change in a capacitance value by an applied voltage is large (a high capacitance value change dependency upon an applied voltage). This disadvantage results from that a depletion region is spread by an applied voltage into a semiconductor region constituting the lower electrode of a MOS type capacitor. A capacitance value change is several tens or more %. JP-A-HEI-7-221599 discloses an approach to mitigating a capacitance value change dependency upon an applied voltage by connecting two MOS type capacitors in parallel and in opposite directions and adjusting an impurity concentration of a semiconductor region (well region) to thereby expand a range (−Vth to +Vth) of positive and negative threshold voltages. However, it does not disclose an approach to mitigating a capacitance value change dependency upon an applied voltage of a capacitor having upper and lower electrodes made of polysilicon or the like and sandwiching a dielectric film.

For a capacitor having upper and lower electrodes made of doped polysilicon and sandwiching a dielectric film, a method of mitigating a capacitance value change dependency upon an applied voltage is known by which concentrations of phosphorus ions implanted into the upper and lower electrodes are made equal (e.g., refer to Japanese Patent No. 3419660). Another known method of mitigating a capacitance value change dependency upon an applied voltage forms a capacitor having equivalently two parallel capacitor regions Ca and Cb as shown in FIG. 16 (e.g., refer to JP-A-HEI-11-54700).

A capacitor shown in FIG. 16 has a semiconductor layer 6 of polysilicon or the like, a dielectric film 7 of silicon oxide and a semiconductor layer 8 of polysilicon or the like stacked on an insulating film 2 covering a semiconductor substrate 1. The semiconductor layer 6 is used as a lower electrode layer and constituted of a first semiconductor region 6A having a high impurity concentration N_{H} and a second semiconductor region 6B having a low impurity concentration N_{L}. The semiconductor layer 8 is used as an upper electrode and has an intermediate impurity concentration N_{M} between the impurity concentrations N_{H} and N_{L}.

FIG. 17 shows a capacitance ratio (C—Co)/Co dependency upon an applied voltage of first to third capacitors having a three-layer structure similar to the capacitor shown in FIG. 16. “Co” represents a capacitance value at an applied voltage of 0, and “C” represents a capacitance value at an applied voltage other than 0 V. A polarity of an applied voltage is minus at the semiconductor layer 6 and plus at the semiconductor layer 8, which is a positive direction.

In the first to third capacitors, the semiconductor layers 6 and 8 are made of a phosphorus doped polysilicon layer and the dielectric film 7 is made of a silicon oxide film. The first capacitor has a phosphorus concentration of the upper electrode layer 8 lower than that of the lower electrode layer 6, and the capacitance change ratio dependency upon an applied voltage has a negative slope as shown by a curve A. The second capacitor has a phosphorus concentration of the upper electrode layer 8 higher than that of the lower electrode layer 6, and the capacitance change ratio dependency upon an applied voltage has a positive slope as shown by a curve B. The third capacitor has a phosphorus concentration of the upper electrode layer 8 equal to that of the lower electrode layer 6, and the capacitance change ratio dependency upon an applied voltage is mitigated in a shape synthesizing the characteristics of the curves A and B, as shown by a curve C.

The capacitor region Ca of the capacitor shown in FIG. 16 has the capacitance change ratio dependency upon an applied voltage corresponding to the curve A shown in FIG. 17, and the capacitor region Cb has the capacitance change ratio dependency upon an applied voltage corresponding to the curve B. Therefore, the capacitance change ratio dependency upon an applied voltage of the whole capacitor corresponds to the curve C synthesizing the curves A and B. If the absolute values of the slopes of the curves A and B are different, the capacitance change ratio dependency upon an applied voltage is optimized by adjusting the area ratio between the semiconductor regions 6A and 6B.

For the capacitor having upper and lower electrode layers of polysilicon or the like sandwiching the dielectric film, the capacitance value change dependency upon an applied voltage can be mitigated by the above-described methods in Japanese Patent No. 3419660 and JP-A-HEI-11-54700. However, an ideal constant capacitance value is not obtained. For example, even if the electrode layers of polysilicon have a high impurity concentration of, e.g., about 10²⁰cm⁻³, a depletion layer is formed more or less in the electrodes when a voltage is applied, so that a capacitance value changes. Since this capacitance value change dependency upon an applied voltage causes a distorted output of an analog integrated circuit, it is desired to suppress the dependency as low as possible if a low distortion output of a circuit is required.

The conventional technique described with reference to Japanese Patent No. 3419660 increases the number of processes because of additional ion implantation processes. The conventional technique described with reference to JP-A-HEI-11-54700 complicates the processes because it is necessary to adjust the impurity concentrations of the semiconductor layers of polysilicon or the like constituting the upper and lower electrode layers and to adjust the impurity concentrations and area ratio of the two semiconductor regions constituting the lower electrode layer.

### SUMMARY OF THE INVENTION

An object of the present invention is to provide a capacitor device which is easy to be manufactured and has a mitigated capacitance value change dependency upon an applied voltage.

According to one aspect of the present invention, there is provided a capacitor device comprising: a substrate having an insulating surface; a first capacitor group formed on the insulating surface of the substrate and having generally a half of a desired capacitance value of the capacitor device; and a second capacitor group formed on the insulating surface of the substrate and having generally a half of the desired capacitance value of the capacitor device, wherein each capacitor constituting the first and second capacitor groups includes a lower electrode layer formed on the insulating surface, a dielectric film formed on the lower electrode layer, and an upper electrode layer formed on the dielectric film and facing the lower electrode layer, at least one of the lower and upper electrode layers includes a semiconductor layer containing conductivity type determining impurities, in the first capacitor group the lower electrode layers of a plurality of capacitors are interconnected to form a first terminal and the upper electrode layers of the capacitors are interconnected to form a second terminal, and in the second capacitor group all of the upper electrode layers of a plurality of capacitors are connected to the first terminal and all of the lower electrode layers of the capacitors are connected to the second terminal.

### BRIEF DESCRIPTION OF THE DRAWINGS

FIGS. 1A is a cross sectional view of a capacitor device according to an embodiment of the present invention, and FIG. 1B is a circuit diagram showing the structure of the capacitor device.

FIG. 2 is a graph showing a capacitance value deviation dependency upon an applied voltage of the capacitor device shown in FIG. 1 having the same phosphorus concentration in polysilicon of upper and lower electrode layers.

FIG. 3 is a graph showing a capacitance value deviation dependency upon an applied voltage of the capacitor device shown in FIG. 1 having a phosphorus concentration in polysilicon of the upper electrode layer lower than that in polysilicon of the lower electrode layer.

FIG. 4 is a cross sectional view illustrating a lower electrode patterning process according to one example of a capacitor device manufacture method according to the present invention.

FIG. 5 is a cross sectional view illustrating an upper electrode patterning process following the process shown in FIG. 4.

FIG. 6 is a cross sectional view illustrating a wiring forming process following the process shown in FIG. 5.

FIG. 7 is a cross sectional view illustrating a sidewall spacer forming process according to another example of a capacitor device manufacture method according to the present invention.

FIG. 8 is a cross sectional view illustrating an upper electrode and first layer wiring forming process following the process shown in FIG. 7.

FIG. 9 is a cross sectional view illustrating a second layer wiring forming process following the process shown in FIG. 8.

FIG. 10 is a plan view showing an upper electrode pattern and a wiring pattern in the process shown in FIG. 8.

FIG. 11 is a cross sectional view illustrating a polysilicon-silicon oxide lamination layer patterning process according to still another example of a capacitor device manufacture method according to the present invention.

FIG. 12 is a cross sectional view illustrating a silicide deposition process following the process shown in FIG. 11.

FIG. 13 is a cross sectional view illustrating a silicide-polysilicon lamination layer patterning process following the process shown in FIG. 12.

FIG. 14 is a cross sectional view illustrating a sidewall spacer forming process following the process shown in FIG. 13.

FIG. 15 is a cross sectional view illustrating a wiring forming process following the process shown in FIG. 14.

FIG. 16 is a cross sectional view showing an example of a conventional capacitor.

FIG. 17 is a graph showing a capacitance change ratio dependency upon an applied voltage of the capacitor shown in FIG. 16.

### DESCRIPTION OF THE PREFERRED EMBODIMENTS

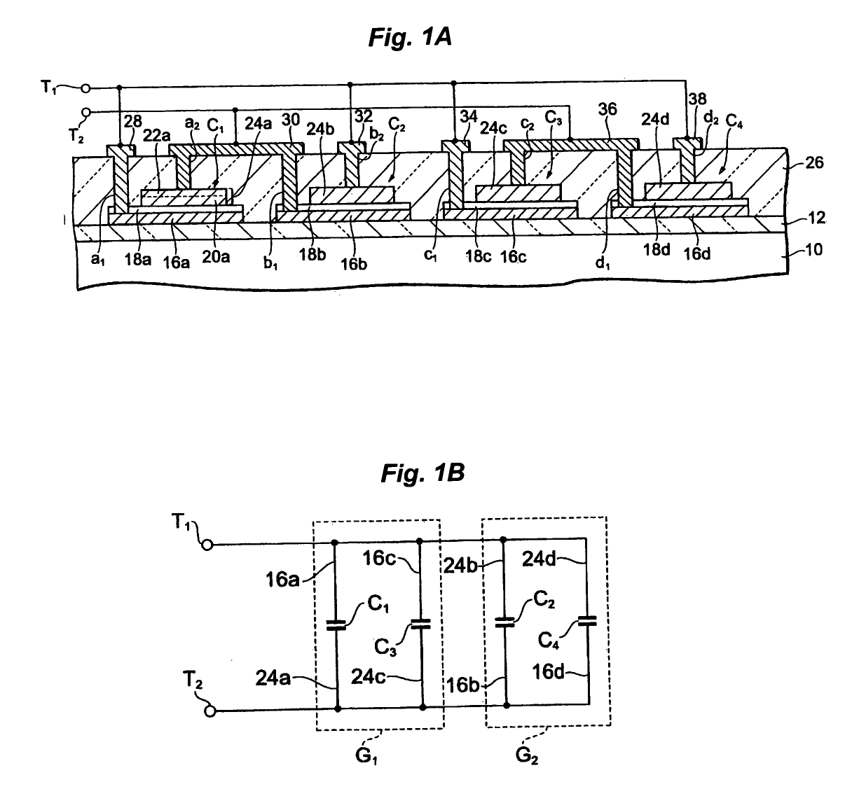

FIG. 1A shows a capacitor device according to an embodiment of the present invention, and the circuit structure of the capacitor device is shown in FIG. 1B.

A semiconductor substrate 10 is made of, e.g., single crystal silicon, and a field insulating film 12 of silicon oxide covers the principal surface of the substrate 10. Four capacitors C₁, to C₄ are formed on the insulating film 12.

The capacitor C₁ is constituted of a lower electrode layer 16a formed on the insulating film 12, a dielectric film 18a formed on the electrode layer 16a, and an upper electrode layer 24a formed on the dielectric film 18a and facing the electrode layer 16a. For example, the lower electrode layer 16a is made of doped polysilicon (low resistance polysilicon), the dielectric film 18a is made of silicon oxide, and the upper electrode layer 24a is made of a lamination (polycide layer) of a doped polysilicon layer 20a and a tungsten silicide layer 22a stacked on the doped polysilicon layer. Phosphorus as n-type impurities is doped in polysilicon of the electrode layers 16a and 24a at a concentration of about 10²⁰cm⁻³. A thickness of the silicon oxide film constituting the dielectric film 18a is, for example, about 15 nm. The lamination of the lower electrode layer 16a and dielectric film 18a has, for example, a rectangular shape, and the upper electrode layer 24a of a rectangular shape smaller than the lamination is stacked on the lamination. The shape of the electrode layers 16a and 24a may be any shape such as circular, ellipsoidal, and polygonal, with the dielectric film 18a being sandwiched therebetween.

The capacitors C₂ to C₄ have similar structures as those of the capacitor C₁. Namely, a lower electrode layer 16b, a dielectric film 18b and an upper electrode layer 24b of the capacitor C₂ have similar structures to those of the upper electrode layer 16a, dielectric film 18a and upper electrode layer 24a. A lower electrode layer 16c, a dielectric film 18c and an upper electrode layer 24c of the capacitor C₃ have similar structures to those of the upper electrode layer 16a, dielectric film 18a and upper electrode layer 24a. A lower electrode layer 16d, a dielectric film 18d and an upper electrode layer 24d of the capacitor C₄ have similar structures to those of the upper electrode layer 16a, dielectric film 18a and upper electrode layer 24a. As shown in FIG. 1B, the capacitors C₁ to C₄ are divided into a first group G₁ including the capacitors C₁ and C₃ and a second group G₂ including the capacitors C₂ and C₄. In the first group G₁, the lower electrode layers 16a and 16c are interconnected to form a terminal T₁ and the upper electrode layers 24a and 24c are interconnected to form a terminal T₂. In the second group G₂, the upper electrode layers 24b and 24d are connected to the terminal T₁ and the lower electrode layers 16b and 16d are connected to the terminal T₂.

FIG. 1A shows a specific example of the connection state shown in FIG. 1B. An interlayer insulating film 26 is formed on the insulating film 12, covering the capacitors C₁ to C₄. Contact holes a₁ to d₁ are formed in the insulating film 26 in correspondence with the lower electrode layers 18a to 18d, and contact holes a₂ to d₂ are formed in the insulating film 26 in correspondence with the upper electrode layers 24a to 24d. The contact holes a₁, b₁, c₁ and d₁ are formed through the dielectric films 18a, 18b, 18c and 18d to reach the lower electrode layers 16a, 16b, 16c and 16d, respectively. Wiring layers 28 and 34 are connected to the lower electrode layers 16a and 16c via the contact holes a₁ an c₁, and to the terminal T₁. A wiring layer 30 is connected on the one hand to the upper electrode layer 24a via the contact hole a₂, on the other hand to the lower electrode layer 16b via the contact hole b₁, and to the terminal T₂. Wiring layers 32 and 38 are connected to the upper electrode layers 24b and 24d via the contact holes b₂ and d₂, respectively, and to the terminal T₁. A wiring layer 36 is connected on the one hand to the upper electrode layer 24c via the contact hole c₂, on the other hand to the lower electrode layer 16d via the contact hole d₁, and to the terminal T₂.

The capacitor device shown in FIG. 1 has a total capacitance value Cₜ=4Cₖ where Cₖ is a capacitance value of each of the capacitors C₁ to C₄, and the total capacitance value of each of the groups G₁ and G₂ is 2Cₖ=C_{t/}2. The first and second groups G₁ and G₂ each bear a half of the total capacitance value (desired capacitance value) Cₜ.

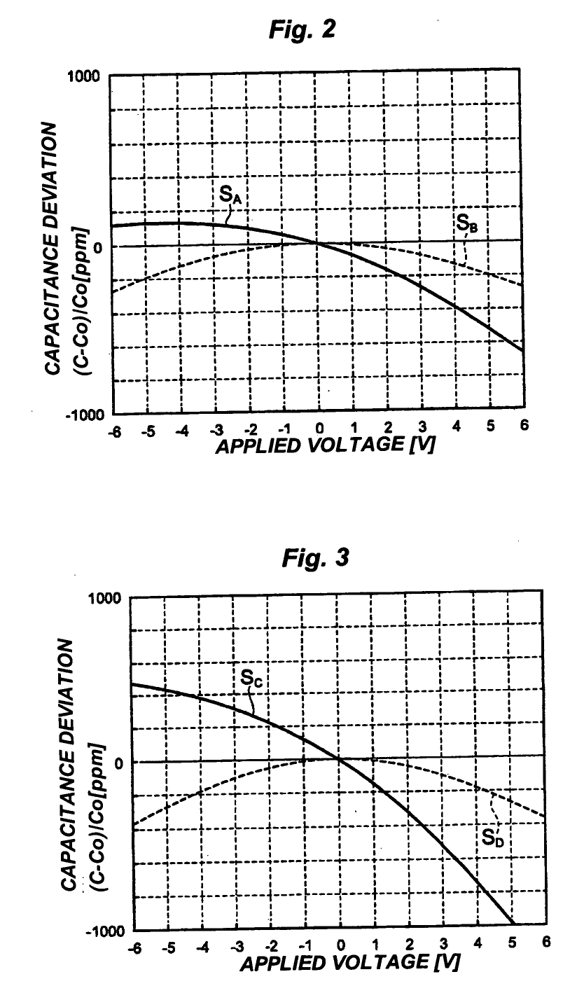

FIG. 2 is a graph showing a capacitance deviation dependency upon an applied voltage of the capacitor device shown in FIG. 1 having the same phosphorus concentration in polysilicon of the upper and lower electrode layers. The abscissa represents an applied voltage “V”, and the ordinate represents a capacitance deviation (C-Co)/Co “ppm” where “Co” is a capacitance value at an applied voltage of 0 V and “C” is a capacitance value at an applied voltage other than 0 V. A polarity of an applied voltage is minus at the terminal T₁ and plus at the terminal T₂, which is a positive direction. A phosphorus concentration in polysilicon of the upper and lower electrode layers was set to 10²⁰cm⁻³ and a thickness of the dielectric film was set to 15 nm.

Under these conditions, a curve S_{A} shown in FIG. 2 shows a capacitance deviation dependency upon an applied voltage wherein the connection of the capacitors C₂ and C₄ to the terminals T₁ and T₂ is reversed relative to the connection shown in FIG. 1B (i.e., the lower electrode layers 16b and 16d are connected to the terminal T₁, and the upper electrode layers 24b and 24d are connected to the terminal T₂). A curve S_{B} shown in FIG. 2 shows a capacitance deviation dependency upon an applied voltage wherein the connection of the capacitors C₂ and C₄ to the terminals T₁ and T₂ is the same as that shown in FIG. 1B. Table 1 shows a comparison of a capacitance deviation between the curves S_{A} and S_{B} at the applied voltages of −5 V and +5 V.

TABLE 1

| Curve | Applied Voltage −5 V | Applied Voltage +5 V |
|---|---|---|
| S_{A} | 130 | −500 |
| S_{B} | −190 | −190 |

As seen from FIG. 2 and Table 1, as compared to the curve S_{A} wherein the capacitors C₂ and C₄ of the second group G₂ are connected in parallel to, and in the same direction as that of, the capacitors C₁ and C₃ of the first group G₁, the curve S_{B} (present invention) wherein the capacitors C₂ and C₄ of the second group G₂ are connected in parallel to, and in the opposite direction to that of, the capacitors C₁ and C₃ of the first group G₁, mitigates the capacitance deviation dependency upon an applied voltage. For example, the capacitance deviation of the curve S_{A} is −500 ppm at +5 V, whereas the capacitance deviation of the curve S_{B} is −190 ppm at +5 V being reduced to a half of or smaller than the curve S_{A}.

FIG. 3 is a graph showing a capacitance deviation dependency upon an applied voltage of the capacitor device shown in FIG. 1 having a phosphorus concentration in polysilicon of the upper electrode layer lower than that in polysilicon of the lower electrode layer. The phosphorus concentration in polysilicon of the upper electrode layer was lower than 10²⁰cm⁻³, and the other conditions and parameters of the graph were the same as those described with reference to FIG. 2.

Similar to the curve S_{A} shown in FIG. 2, a curve S_{C} shown in FIG. 3 shows a capacitance deviation dependency upon an applied voltage wherein the connection of the capacitors C₂ and C₄ of the second group T₂ are connected in parallel to, and in the same direction as that of, the capacitors of the first group G₁. In contrast, similar to the curve S_{B} shown in FIG. 2, a curve S_{D} shown in FIG. 3 shows a capacitance deviation dependency upon an applied voltage wherein the connection of the capacitors C₂ and C₄ of the second group T₂ are connected in parallel to, and in the opposite direction to that of, the capacitors of the first group G₁. Table 2 shows a comparison of a capacitance deviation between the curves S_{c} and S_{D} at the applied voltages of −5 V and +5 V.

TABLE 2

| Curve | Applied Voltage −5 V | Applied Voltage +5 V |
|---|---|---|
| S_{C} | 440 | −970 |
| S_{D} | −260 | −260 |

As seen from FIG. 3 and Table 2, the capacitance deviation dependency upon an applied voltage is mitigated in the case (present invention) of the curve S_{D} more than the case of the curve S_{C}. For example, the capacitance deviation of the curve S_{C} is −970 ppm at +5 V, whereas the capacitance deviation of the curve S_{D} is −260 ppm at +5 V being reduced to one third of or smaller than the curve S_{C}. Therefore, even if an amount of impurities doped in the polysilicon electrode layer is changed by a variation in manufacture processes, it is possible to maintain low a capacitance value change dependency upon an applied voltage.

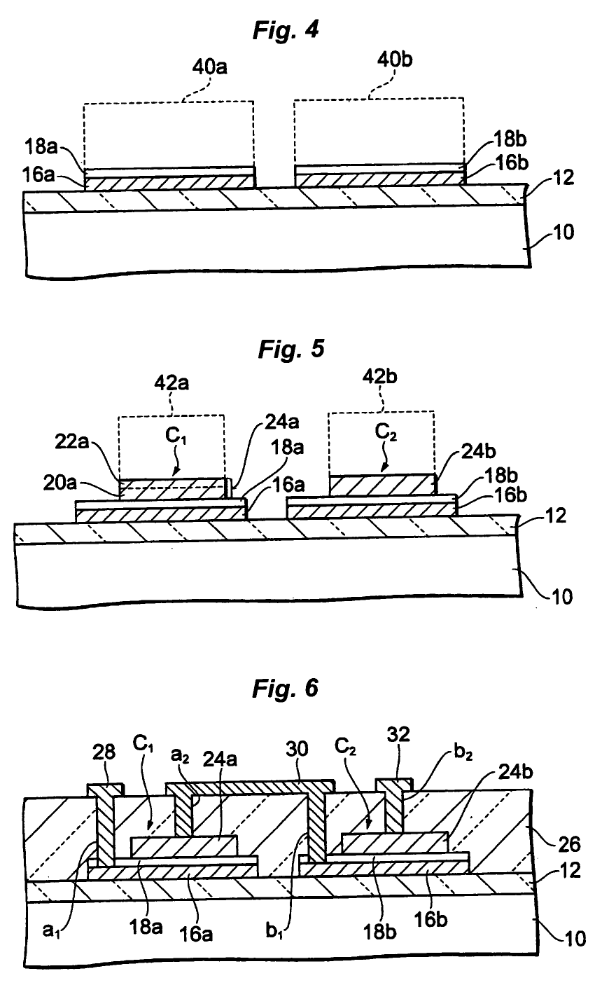

FIGS. 4 to 6 illustrate an example of a capacitor device manufacture method according to the present invention. In FIGS. 4 to 6, like parts to those shown in FIG. 1 are represented by identical symbols, and the detailed description thereof is omitted. Since the capacitors C₁ and C₂ and the capacitors C₃ and C₄ are manufactured by the same processes, description will be made on the manufacture method for the capacitors C₁ and C₂ as a representative.

In the process shown in FIG. 4, a polysilicon layer to be used for forming electrode layers 16a and 16b is deposited by chemical vapor deposition (CVD) on an insulating film 12, covering a semiconductor substrate 10. A thickness of the polysilicon layer may be, for example, 150 nm. Phosphorus is doped in the polysilicon layer during or after deposition at a concentration of 10²⁰cm⁻³ in order to lower the resistance thereof.

A silicon oxide film to be used for forming dielectric films 18a and 18b is deposited on the polysilicon layer by CVD. A thickness of the polysilicon layer may be, for example, 15 nm. The silicon oxide film may be formed by thermally oxidizing the polysilicon layer.

Resist layers 40a and 40b having shapes conformal to desired lower electrode patterns are formed on the silicon oxide film by photolithography. By using the resist layers 40a and 40b as a mask, a lamination of the polysilicon layer and silicon oxide layer is patterned by dry etching to thereby form lower electrode layers 16a and 16b made of left polysilicon layers and dielectric films 18a and 18b made of left silicon oxide films. The resist layers 40a and 40b are thereafter removed by ashing.

In the processes shown in FIG. 5, a polysilicon layer and a tungsten silicide layer to be used for forming upper electrodes 24a and 24b are sequentially deposited on the insulating film 12 by CVD, covering the lower electrode layers 16a and 16b, and dielectric films 18a and 18b. Thicknesses of both the polysilicon layer and tungsten silicide layer may be 100 nm. Phosphorus is doped in the polysilicon layer during or after deposition at a concentration of 10²⁰cm⁻³ in order to lower the resistance thereof. The tungsten silicide layer may be formed by sputtering, or by depositing a tungsten layer by sputtering and thereafter silicidating the tungsten layer and polysilicon layer by heat treatment.

Resist layers 42a and 42b having shapes conformal to desired upper electrode patterns are formed on the polycide layer (a lamination of the polysilicon layer and the tungsten silicide layer stacked thereon). By using the resist layers 42a and 42b as a mask, the polycide layer is patterned by dry etching to thereby form upper electrode layers 24a and 24b made of left polycide layers. The upper electrode layer 24a is made of a lamination of a left polysilicon layer 20a and a left tungsten silicide layer 22a, and the lower electrode layer 24b is made of a similar lamination to that of the upper electrode layer 24a.

With the above-described processes, a capacitor C₁ and a capacitor C₂ are formed on the insulating film 12, the capacitor C₁ being constituted of the lower electrode layer 16a, dielectric film 18a and upper electrode layer 24a, and the capacitor C₂ being constituted of the lower electrode layer 16b, dielectric film 18b and upper electrode layer 24b.

In the process shown in FIG. 6, an interlayer insulating film 26 is formed on the substrate upper surface, covering the capacitors C₁ and C₂. For example, the interlayer insulating film 26 may be formed by forming a silicon oxide film by CVD, coating or the like. Contact holes a₁ and b₁ corresponding to the lower electrode layers 16a and 16b and contact holes a₂ and b₂ corresponding to the upper electrode layers 24a and 24b are formed in the interlayer insulating film 26 by photolithography and dry etching. The contact holes a₁ and b₁ are formed through the dielectric films 18a and 18b to reach the lower electrode layers 16a and 16b. Thereafter, a wiring layer of Al alloy or the like is formed on the substrate upper surface by sputtering or the like, and patterned by photolithography and dry etching to thereby form wiring layers 28, 30 and 32. The wiring layers 28 and 32 are connected to the electrode layers 16a and 24b via the contact holes a₁ and b₂, respectively, and the wiring layer 30 interconnects the electrode layers 24a and 16b via the contact holes a₂ and b₁, respectively. If metal oxide semiconductor (MOS) type transistors and the like are to be formed on the substrate 10, some of the above-described processes may be shared by the transistor forming processes.

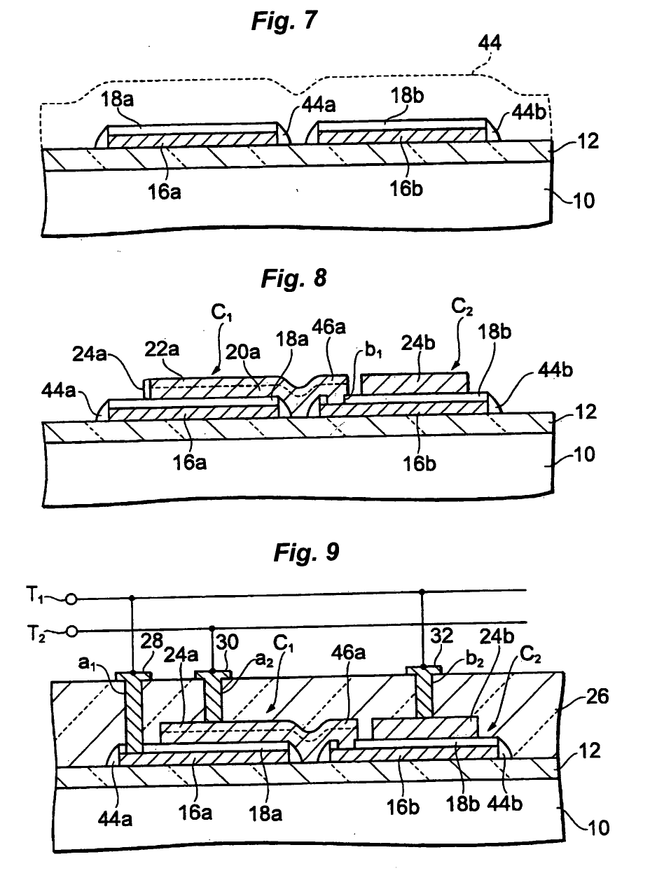

FIGS. 7 to 9 illustrate another example of the capacitor device manufacture method according to the present invention. In FIGS. 7 to 9, like parts to those shown in FIG. 1 and FIGS. 4 to 6 are represented by identical symbols, and the detailed description thereof is omitted. Since the capacitors C₁ and C₂ and the capacitors C₃ and C₄ are manufactured by the same processes, description will be made on the manufacture method for the capacitors C₁ and C₂ as a representative.

The process shown in FIG. 7 is a sidewall spacer forming process following the process shown in FIG. 4. In this process, an insulating film 44 such as a silicon oxide film is deposited on the substrate upper surface by CVD, covering the lower electrode layers 16a and 16b and dielectric films 18a and 18b, and thereafter etched back by anisotropical dry etching to thereby form insulating sidewall spacers 44a and 44b made of left insulating films. The sidewall spacers 44a are formed on the insulating film 12, covering the sidewalls of a lamination of the lower electrode layer 16a and dielectric film 18a, and the sidewall spacers 44b are formed on the insulating film 12, covering the sidewalls of a lamination of the lower electrode layer 16b and dielectric film 18b.

In the process shown in FIG. 8, a contact hole b₁ is formed through the dielectric film 18b by photolithography and dry etching, reaching the lower electrode layer 16b. Similar to the process described with reference to FIG. 5, an upper electrode 24a is formed on the dielectric film 18a and an upper electrode 24b is formed on the dielectric film 18b. By using this process, a wiring layer 46a is also formed. Similar to the upper electrode layer 24a, the wiring layer 46a is made of a lamination of a polysilicon layer 20a and a tungsten silicide layer 22a stacked on the polysilicon layer, and connects the upper electrode layer 24a to the lower electrode layer 16b via the contact hole b₁. FIG. 10 illustratively shows a plan pattern of the upper electrode layers 24a and 24b and a plan pattern of the wiring layer 46a. FIG. 8 is a cross sectional view taken along line A-A′ shown in FIG. 10. The wiring layer 46a is electrically insulated from the lower electrode layer 16a by the sidewall spacer 44a.

With the above-described processes, a capacitor C₁ and a capacitor C₂ are formed on the insulating film 12, the capacitor C₁ being constituted of the lower electrode layer 16a, dielectric film 18a and upper electrode layer 24a, and the capacitor C₂ being constituted of the lower electrode layer 16b, dielectric film 18b and upper electrode layer 24b.

In the process shown in FIG. 9, an interlayer insulating film 26 is formed on the substrate upper surface, covering the capacitors C₁ and C₂. For example, the interlayer insulating film 26 may be formed by forming a silicon oxide film by CVD, coating or the like. A contact hole a₁ corresponding to the lower electrode layer 16a and contact holes a₂ and b₂ corresponding to the upper electrode layers 24a and 24b are formed in the interlayer insulating film 26 by photolithography and dry etching. The contact hole a₁ is formed through the dielectric film 18a to reach the lower electrode layer 16a. Thereafter, a wiring layer of Al alloy or the like is formed on the substrate upper surface by sputtering or the like, and patterned by photolithography and dry etching to thereby form wiring layers 28, 30 and 32. The wiring layers 28, 30 and 32 are connected to the electrode layers 16a, 24a and 24b via the contact holes a₁, a₂ and b₂, respectively. If MOS type transistors and the like are to be formed on the substrate 10, some of the above-described processes may be shared by the transistor forming processes.

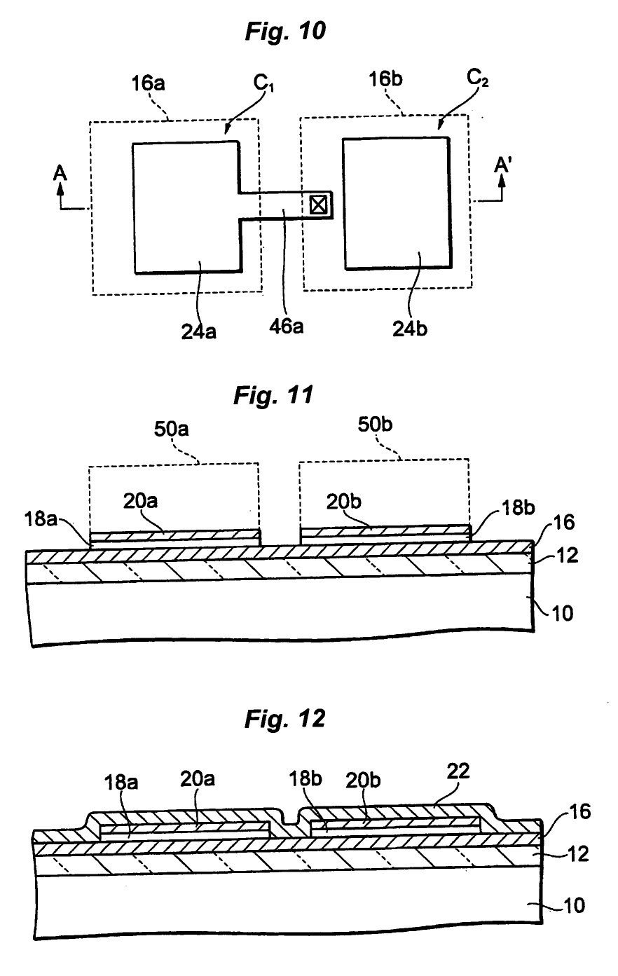

FIGS. 11 to 15 illustrate still another example of the capacitor device manufacture method according to the present invention. In FIGS. 11 to 15, like parts to those shown in FIG. 1 and FIGS. 4 to 6 are represented by identical symbols, and the detailed description thereof is omitted. Since the capacitors C₁ and C₂ and the capacitors C₃ and C₄ are manufactured by the same processes, description will be made on the manufacture method for the capacitors C₁ and C₂ as a representative.

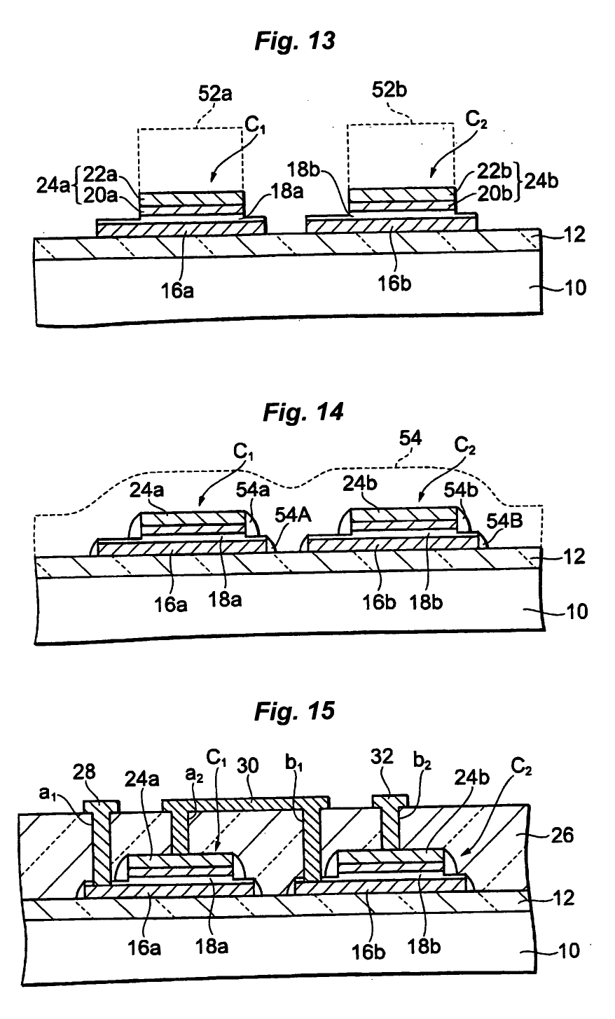

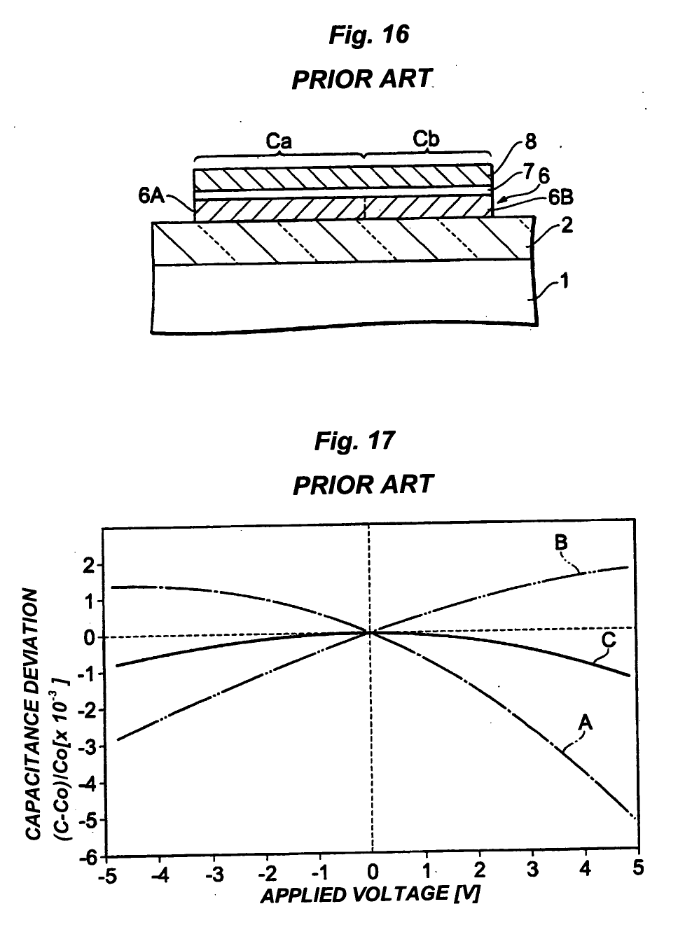

In the process shown in FIG. 11, a polysilicon layer 16 to be used for forming electrode layers 16a and 16b (refer to FIG. 13) is deposited on an insulating film 12 by CVD. A thickness of the polysilicon layer 16 may be, for example, 150 nm. Phosphorus is doped in the polysilicon layer during or after deposition at a concentration of 10²⁰cm⁻³ in order to lower the resistance thereof. A silicon oxide film to be used for forming dielectric films 18a and 18b is deposited on the polysilicon layer 16 by CVD or thermal oxidation. Thereafter, an upper polysilicon layer to be used for forming polysilicon layers 20a and 20b is deposited on the silicon oxide film by CVD. Phosphorus is doped also in the upper polysilicon layer in a manner similar to that described with reference to the polysilicon layer 16.

Next, resist layers 50a and 50b having shapes conformal to desired lower electrode patterns are formed on the upper polysilicon layer by photolithography. By using the resist layers 50a and 50b as a mask, a lamination of the silicon oxide layer and upper polysilicon layer is patterned by dry etching to thereby leave upper polysilicon layer portions 20a and 20b and form dielectric films 18a and 18b made of left silicon oxide films. The resist layers 50a and 50b are thereafter removed by ashing.

In the processes shown in FIG. 12, a tungsten silicide layer 22 is formed on the polysilicon layer 16 by CVD, sputtering or the like, covering the dielectric films 18a and 18b and upper polysilicon layer portions 20a and 20b.

In the process shown in FIG. 13, resist layers 52a and 52b having shapes conformal to desired upper electrode patterns are formed on the tungsten silicide layer 22. By using the resist layers 52a and 52b as a mask, a lamination of the upper polysilicon layer portion 20a and tungsten silicide layer 22 and a lamination of the upper polysilicon layer portion 20b and tungsten silicide layer 22 are patterned to thereby form upper electrode layers 24a and 24b. The upper electrode layer 24a is a lamination of a left portion of the upper polysilicon layer portion 20a and a left portion 22a of the tungsten silicide layer 22, and the upper electrode layer 24b is a lamination of a left portion of the upper polysilicon layer 20b and a left portion 22b of the tungsten silicide layer 22.

In the dry etching shown in FIG. 13, the polysilicon layer 16 is patterned by using the dielectric films 18a and 18b as a mask to thereby form lower electrode layers 16a and 16b made of left portions of the polysilicon layer 16. Since the dielectric films 18a and 18b were pattered in the process shown in FIG. 11 into shapes conformal to the lower electrode patterns, in the dry etching shown in FIG. 13, the dielectric films 18a and 18b are used as an etching stopper during polycide etching for the upper polysilicon portion 20a, 22, . . . , whereas the dielectric films 18a and 18b are used as an etching mask during etching for the polysilicon layer 16. Therefore, the dielectric films 18a and 18b not covered by the resist layers 52a and 52b are slightly thinned. The resist layers 52a and 52b are thereafter removed by ashing.

With the above-described processes, a capacitor C₁ and a capacitor C₂ are formed on the insulating film 12, the capacitor C₁ being constituted of the lower electrode layer 16a, dielectric film 18a and upper electrode layer 24a, and the capacitor C₂ being constituted of the lower electrode layer 16b, dielectric film 18b and upper electrode layer 24b.

In the process shown in FIG. 14, if necessary, insulating sidewall spacers 54A, 54B, 54a and 54b are formed. Namely, an insulating film 54 such as a silicon oxide film is deposited on the substrate upper surface by CVD, covering the lower electrode layers 16a and 16b, dielectric films 18a and 18b and upper electrode layers 24a and 24b, and thereafter etched back by anisotropical dry etching to thereby form insulating sidewall spacers 54A, 54B, 54a and 54b made of left insulating films. The sidewall spacers 54A are formed on the insulating film 12, covering the sidewalls of a lamination of the lower electrode layer 16a and dielectric film 18a, and the sidewall spacers 54B are formed on the insulating film 12, covering the sidewalls of a lamination of the lower electrode layer 16b and dielectric film 18b. The sidewall spacers 54a are formed on the dielectric film 18a, covering the sidewalls of the upper electrode layer 24a, and the sidewall spacers 54b are formed on the dielectric film 18b, covering the sidewalls of the upper electrode layer 24b.

In the process shown in FIG. 15, in the manner similar to that described with reference to FIG. 6, an interlayer insulating film 26 is formed on the substrate upper surface, covering the capacitors C₁ and C₂, and contact holes a₁, a₂, b₁ and b₂ are formed in the interlayer insulating film 26. In the manner similar to that described with reference to FIG. 6, wiring layers 28 and 32 are formed being connected to the electrode layers 16a and 24b via the contact holes a₁ and b₂, respectively, and a wiring layer 30 is formed interconnecting the electrode layers 24a and 16b via the contact holes a₂ and b₁, respectively. If MOS type transistors and the like are to be formed on the substrate 10, some of the above-described processes may be shared by the transistor forming processes. The manufacture method described above with reference to FIGS. 11 to 15 is suitable for forming a capacitor device by sharing some of the manufacture processes of forming MOS type transistors and resistors. A specific example of shared manufacture processes is described in U.S. Pat. No. 5,618,749, which is incorporated herein by reference, and the description thereof is omitted.

According to the capacitor device manufacture methods described above with reference to FIGS. 4 to 15, a plurality of capacitors having the same pattern are formed on an insulating surface of a substrate, and connected by wirings of one or more layers. It is not necessary to add specific processes such as ion implantation as in the case of a conventional method. It is therefore possible to manufacture a capacitor device of the present invention with ease and at low cost.

The present invention is not limited to the embodiments described above, but various modifications are possible. For example, the following modifications are possible.

(1) The dielectric films 18a, . . . are not limited to a silicon oxide film, but a single layer film such as a silicon nitride film, a silicon oxynitride film and a tantalum oxide film, or a two-or three-layer lamination film of a combination of these films may also be used.

(2) The upper electrode layers 24a, . . . are not limited to a polycide layer, but the upper electrode layer may be made of only a semiconductor layer of such as low resistance polysilicon, or only a metal layer of refractory metal such as W, Mo and Ti or its silicide. The lower electrode layers 16a, . . . and upper electrode layers 24a may be made of a semiconductor layer, the lower electrode layers may be made of a semiconductor layer and the upper electrode layers may be made of a metal layer, or vice versa.

(3) The number of capacitors constituting the capacitor device is not limited to four, but a larger number of capacitors may also be used. If the number of capacitors is odd, the number of capacitors in the first group G₁ becomes different from the number of capacitors in the second group G₂ (e.g., twenty capacitors in G₁ and twenty one capacitors in G₂). Even if there is a capacitance difference between two groups, it is allowable if the smaller capacitance of the two groups is 90% or larger of the larger capacitance. It can be defined that if the smaller capacitance of the two groups is 90% or larger of the larger capacitance, a capacitance value of one group or the other group occupies generally a half of the total synthesized capacitance value.

According to the capacitance devices of the embodiments, a first capacitor group and a second capacitor group each having generally a half of a desired capacitance value of each capacitance device are connected in parallel, so that the desired capacitance value is a total sum of two halves of the capacitance value. In the parallel connection, the lower electrode layers and upper electrode layers of the first capacitor group are reversely connected to the upper electrode layers and lower electrode layers of the second capacitor group. Therefore, the capacitance value change dependency upon an applied voltage is cancelled out between the first and second capacitor groups.

When the first and second capacitor groups are connected in parallel, low resistance metal wirings can be used. It is therefore possible to suppress serial parasitic resistance components to be small even if a large capacitance capacitor device is manufactured.

The capacitance value dependency upon an applied voltage of each capacitor in the first and second capacitor groups varies because of manufacture process variation. Therefore, if the first and second capacitor groups are connected in parallel and in the same direction, the capacitance value dependency upon an applied voltage becomes considerably high. As described above, as the first and second capacitor groups are connected in parallel and in reversed directions, it is possible to suppress low the capacitance value change dependency upon an applied voltage of the whole capacitance device. Each capacitor can be formed easily by using similar patterns, and specific processes such as ion implantation are not required additionally.

The capacitance value change dependency upon an applied voltage is mitigated by connecting the first and second capacitor groups in parallel and in reversed directions. A large capacity and high precision capacitor device can therefore be realized with advantageous effects. Since specific processes are not required for each capacitor, it is advantageous in that a capacitor device can be manufactured easily and at low cost.

The present invention has been described in connection with the preferred embodiments. The invention is not limited only to the above embodiments. It will be apparent to those skilled in the art that other various modifications, improvements, combinations, and the like can be made.

What we claim are:

1. A capacitor device comprising:
a substrate having an insulating surface;
a first capacitor formed on said insulating surface of said substrate; and
a second capacitor formed on said insulating surface of said substrate,
wherein each of said first and second capacitors includes a lower electrode layer formed on said insulating surface, a dielectric film formed on said lower electrode layer, and an upper electrode layer formed on said dielectric film, at least one of said lower and upper electrode layers includes a semiconductor layer containing conductivity type determining impurities, said lower electrode layer of the first capacitor and said upper electrode layer of the second capacitor are electrically connected, and said upper electrode layer of the first capacitor and said lower electrode layer of the second capacitor are electrically connected.

2. The capacitor device according to claim 1, wherein said lower electrode layer contains doped polysilicon.

3. The capacitor device according to claim 1, wherein said upper electrode layer contains doped polysilicon.

4. A capacitor device comprising:
a substrate having an insulating surface;
a first capacitor group formed on said insulating surface of said substrate and having generally a half of a desired capacitance value of the capacitor device; and
a second capacitor group formed on said insulating surface of said substrate and having generally a half of the desired capacitance value of the capacitor device,
wherein each capacitor constituting said first and second capacitor groups includes a lower electrode layer formed on said insulating surface, a dielectric film formed on said lower electrode layer, and an upper electrode layer formed on said dielectric film and facing said lower electrode layer, at least one of said lower and upper electrode layers includes a semiconductor layer containing conductivity type determining impurities, in said first capacitor group said lower electrode layers of a plurality of capacitors are interconnected to form a first terminal and said upper electrode layers of the capacitors are interconnected to form a second terminal, and in said second capacitor group all of said upper electrode layers of a plurality of capacitors are connected to said first terminal and all of said lower electrode layers of the capacitors are connected to said second terminal.

5. The capacitor device according to claim 4, wherein said lower electrode layer contains doped polysilicon.

6. The capacitor device according to claim 4, wherein said upper electrode layer contains doped polysilicon.

7. A semiconductor device comprising:
a semiconductor substrate;
a semiconductor device formed in said semiconductor substrate;
an insulating film formed on said semiconductor substrate;
a first capacitor formed on said insulating film; and
a second capacitor formed on said insulating film,
wherein each of said first and second capacitors includes a lower electrode layer formed on said insulating surface, a dielectric film formed on said lower electrode layer, and an upper electrode layer formed on said dielectric film, at least one of said lower and upper electrode layers includes a semiconductor layer containing conductivity type determining impurities, said lower electrode layer of the first capacitor and said upper electrode layer of the second capacitor are electrically connected, and said upper electrode layer of the first capacitor and said lower electrode layer of the second capacitor are electrically connected.

8. The capacitor device according to claim 7, wherein said lower electrode layer contains doped polysilicon.

9. The capacitor device according to claim 7, wherein said upper electrode layer contains doped polysilicon.
